(19) United States
(12) Patent Application Publication
(10) Pub. No.: US 2015/0311415 A1
(43) Pub. Date: Oct. 29, 2015

(54) LIGHT-EMITTING DEVICE HAVING EXCELLENT CURRENT SPREADING EFFECT AND METHOD FOR MANUFACTURING SAME

(71) Applicant: ILJIN LED CO., LTD., Ansan-si, Gyeonggi-do (KR)

(72) Inventors: Jung-Sub SONG, Daejeon (KR); Dong-Woo KIM, Seoul (KR); Keuk KIM, Seongnam-si, Gyeonggi-do (KR); Won-Jin CHOI, Seongnam-si, Gyeonggi-do (KR); Seung-Joo HWANG, Suncheon-si, Jeollanam-do (KR)

(21) Appl. No.: 14/646,526

(22) PCT Filed: Nov. 22, 2013
(86) PCT No.: PCT/KR2013/010705

§ 371 Date: May 21, 2015

(30) Foreign Application Priority Data
Nov. 23, 2012 (KR) 10-2012-0133754

(51) Int. Cl. H01L 33/62; H01L 27/15; H01L 33/08; H01L 33/38; H01L 33/24; H01L 33/00

(52) U.S. Cl. CPC H01L 33/62; H01L 33/24; H01L 33/005; H01L 33/08; H01L 33/38; H01L 27/156

(57) ABSTRACT

Disclosed are a light-emitting device having excellent light-emitting efficiency by a current spreading effect and a method for manufacturing the same. The light-emitting device, according to the present invention, comprises: a light-emitting structure which is formed on a substrate, includes a first semiconductor layer, an active layer, and a second semiconductor layer, and in which a plurality of trenches are formed up to the second semiconductor layer and the active layer; a first electrode formed to come in contact with the second semiconductor layer of the light-emitting structure; and a second electrode formed to come in contact with the first semiconductor layer along at least one edge of the substrate.

### TECHNICAL FIELD

The present invention relates, in general, to a light-emitting device and a method of manufacturing the same and, more particularly, to a light-emitting device having an excellent current spreading effect and a method of manufacturing the same.

### BACKGROUND ART

A light-emitting device includes an n type semiconductor layer, a p type semiconductor layer, and an active layer disposed between the semiconductor layers and configured to emit light by a recombination of electrons/holes. Furthermore, the light-emitting device includes an n-side electrode for supplying electrons to the n type semiconductor layer and a p-side electrode for supplying holes to the p type semiconductor layer.

The light-emitting device may be divided into a lateral structure and a vertical structure depending on the location of an electrode. In general, the lateral structure and the vertical structure are determined depending on whether a substrate used in the light-emitting device is electrically conductive. For example, a light-emitting device in which a substrate having electrical insulation, such as a sapphire substrate, is used is chiefly implemented to have the lateral structure.

In the case of a light-emitting device having such a lateral structure, the p-side electrode may be formed right on the p type semiconductor layer. In contrast, the n-side electrode is formed in the state in which some region of the n type semiconductor layer has been exposed because the p type semiconductor layer and the active layer are partially removed by mesa etching.

In a light-emitting device having such a lateral structure, a light-emitting area is lost due to mesa etching, and a current flow is laterally formed. As a result, it is difficult to achieve uniform current spreading in the entire area, thereby reducing light-emitting efficiency.

If a large-sized light-emitting device is implemented for a high output, attempts are made to achieve uniform current spreading in the entire light-emitting area by providing an electrode structure, such as a finger. In this case, however, light-emitting efficiency may be reduced because the extraction of light is restricted by the finger or the absorption of light is caused by an electrode.

A prior art related to the present invention includes Korean Patent Application Publication No. 10-0665302 (Jan. 4, 2007). This document discloses a flip chip type light emitting device in which a plurality of light emitting cells is arrayed.

### DISCLOSURE

### Technical Problem

An object of the present invention is to provide a light-emitting device capable of reducing a process cost and exhibiting an excellent current spreading effect and a method of manufacturing the same.

### Technical Solution

In accordance with an aspect of the present invention, there is provided a light-emitting device, including a light-emitting structure formed over a substrate and configured to include a first semiconductor layer, an active layer, and a second semiconductor layer and to have a plurality of trenches formed up to the second semiconductor layer and the active layer, a first electrode formed to come in contact with the second semiconductor layer of the light-emitting structure, and a second electrode formed to come in contact with the first semiconductor layer of the light-emitting structure along at least one edge of the substrate.

In this case, part of or the entire second electrode may be formed of the same construct as part of or the entire first electrode.

In accordance with another aspect of the present invention, there is provided a method of manufacturing a light-emitting device, including forming a light-emitting structure including a first semiconductor layer, an active layer, and a second semiconductor layer over a substrate, forming a plurality of trenches by etching at least the second semiconductor layer and the active layer, and forming part of or the entire second electrode using the same construct as the construct of part of or the entire first electrode along at least one edge of the substrate over the first semiconductor layer while forming the first electrode over the second semiconductor layer.

### Advantageous Effects

The light-emitting device in accordance with an embodiment of the present invention can relatively improve current spreading efficiency and thus improve light-emitting efficiency because an electrode formed along at least one edge of the substrate is electrically connected to a lower semiconductor layer.

Furthermore, in accordance with an embodiment of the present invention, a light-emitting device can be fabricated using a reduced process cost because an electrode connected to a lower semiconductor layer is formed of the same construct as part of or the entire electrode connected to an upper semiconductor layer through a simultaneous process.

### DESCRIPTION OF DRAWINGS

FIG. 1 is a plan view illustrating a light-emitting device in accordance with an embodiment of the present invention.

FIG. 2 is an enlarged cross-sectional view of the light-emitting device taken along line A-A′ of FIG. 1.

FIG. 3 is an enlarged cross-sectional view of the light-emitting device taken along line B-B′ of FIG. 1.

### BEST MODE

The merits and characteristics of the present invention and a method for achieving the merits and characteristics will become more apparent from embodiments described in detail later in conjunction with the accompanying drawings. However, the present invention is not limited to the disclosed embodiments, but may be implemented in various different ways. The embodiments are provided to only complete the disclosure of the present invention and to allow those skilled in the art to understand the category of the present invention. The present invention is defined by the category of the claims. The same reference numbers will be used to refer to the same or similar parts throughout the drawings.

Hereinafter, a light-emitting device capable of reducing a process cost and exhibiting an excellent current spreading effect and a method of manufacturing the same in accordance with embodiments of the present invention are described in detail with reference to the accompanying drawings.

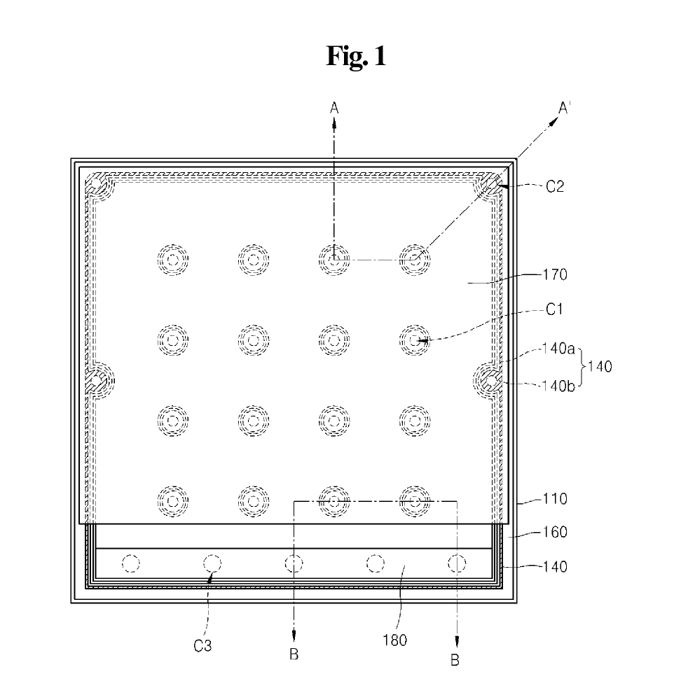

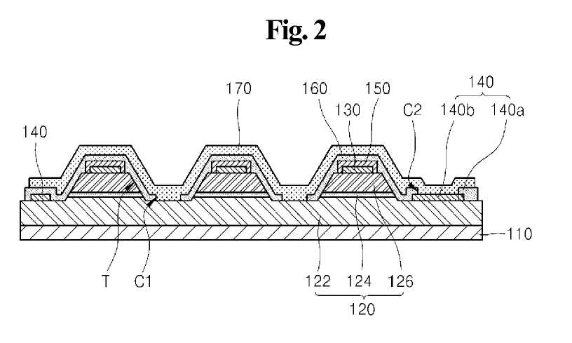

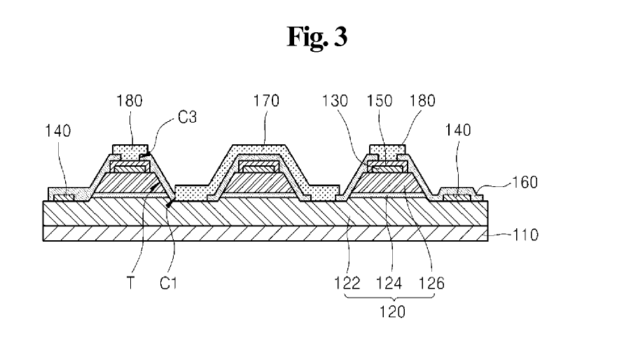

FIG. 1 is a plan view illustrating a light-emitting device in accordance with an embodiment of the present invention, FIG. 2 is an enlarged cross-sectional view of the light-emitting device taken along line A-A′ of FIG. 1, and FIG. 3 is an enlarged cross-sectional view of the light-emitting device taken along line B-B′ of FIG. 1.

Referring to FIGS. 1 to 3, the illustrated light-emitting device includes a substrate 110, a light-emitting structure 120, a first electrode 130, and a second electrode 140. The light-emitting device in accordance with an embodiment of the present invention may further include a covering layer 150, an insulating layer 160, a first bump 170, and a second bump 180.

First, an overall shape of the light-emitting device is described. The light-emitting structure 120 including a plurality of trenches T spaced apart from each other is formed on the substrate 110. The first electrode 130 is formed on the second semiconductor layer 126 of the light-emitting structure 120. The second electrode 140 is formed along the edge of the substrate 110 on the first semiconductor layer 122 of the light-emitting structure 120.

The light-emitting structure 120 includes the first semiconductor layer 122, an active layer 124, and the second semiconductor layer 126 from the bottom. Each of the plurality of trenches T may be formed in at least the second semiconductor layer 126 and the active layer 124.

The first semiconductor layer 122 may be made of n type semiconductor materials into which n type impurities, such as silicon (Si), have been doped, or may be made of p type semiconductor materials into which p type impurities, such as magnesium (Mg), have been doped. If the first semiconductor layer 122 is made of n type semiconductor materials, the second semiconductor layer 126 is made of p type semiconductor materials. If the first semiconductor layer 122 is made of p type semiconductor materials, the second semiconductor layer 126 is made of n type semiconductor materials.

Each of the first semiconductor layer 122 and the second semiconductor layer 126 may be made of an inorganic semiconductor, for example, a GaN-series semiconductor, ZnO-series semiconductor, GaAs-series semiconductor, GaP-series semiconductor, or GaAsP-series semiconductor. In addition, each of the first and the second semiconductor layers 122, 126 may be properly selected from a group consisting of a III-V group semiconductor, a II-VI group semiconductor, and Si and made of the selected materials.

Each of the first semiconductor layer 122 and the second semiconductor layer 126 may have a single layer or multiple layers, and may be grown using a semiconductor layer growth process, such as a metal organic chemical vapor deposition (MOCVD) method, a molecular beam epitaxy (MBE) method, or a hydride vapor phase epitaxy (HVPE) method that are known in the present technical field.

The active layer 124 interposed between the first and the second semiconductor layers 122, 126 emits light of specific energy by a recombination of electrons and holes and may have a multi-quantum well (MQW) structure in which a quantum well layer and a quantum barrier layer are alternately stacked. For example, an InGaN/GaN structure may be used as the MQW structure. By its nature, the active layer 124 may control the wavelength of emitted light by controlling a composition ratio of constituent materials.

The light-emitting structure 120 may emit light selected from light of an infrared region to light of an ultraviolet region depending on the characteristics of the active layer 124. Such a light-emitting structure 120 employs a phenomenon in which it generates minority carriers (electrons or holes) injected using the p-n junction structure of a semiconductor and emits light by a recombination of the minority carriers.

In an embodiment of the present invention, the plurality of trenches T formed in the light-emitting structure 120 is formed by etching the second semiconductor layer 126 and the active layer 124. The plurality of trenches T is formed for a contact between the first semiconductor layer 122 and the second electrode 140.

A plurality of the trenches T may be spaced part from each other and formed as illustrated for a smooth contact with the first bump 170 and may be formed up to the edge area of the substrate 110.

The trench T may have a mesa structure whose width is downward narrowed. In this case, the trench T may be formed by sequentially etching the second semiconductor layer 126 and the active layer 124 using a common mesa etching process. Accordingly, the first semiconductor layer 122 is exposed.

When the mesa etching process is performed, the trench T may be formed by additionally etching part of the first semiconductor layer 122 along with the second semiconductor layer 126 and the active layer 124. This has been illustrated in FIGS. 2 and 3.

Although not illustrated, the light-emitting structure 120 may further include a buffer layer, such as aluminum nitride (AlN) materials, between the first semiconductor layer 122 and the substrate 110 in order to reduce a lattice defect attributable to the growth of the first semiconductor layer 122. An undoped semiconductor layer may be additionally interposed between the buffer layer and the first semiconductor layer 122 in order to increase the crystallinity of the first semiconductor layer 122. Furthermore, an electron blocking layer (EBL) made of materials, such as p type AlGaN, may be further formed between the active layer 124 and the second semiconductor layer 126.

The substrate 110 to which an embodiment of the present invention is applied may be a substrate for semiconductor growth, including a first region and a second region. In this case, the first region is defined as a region corresponding to the first bump 170, and the second region is defined as a region corresponding to the second bump 180.

For example, the substrate 110 may be made of any one selected from sapphire, Al₂O₃, SiC, ZnO, Si, GaAs, GaP, MgAl₂O₄, MgO, LiAlO₂, LiGaO₂, LiAl₂O₃, BN, AlN, and GaN. If the light-emitting device in accordance with an embodiment of the present invention is used in the form of a flip chip, the substrate 110 functions as a window for externally emitting light generated by the active layer 124 of the light-emitting structure 120 via the first semiconductor layer 122.

If the substrate 110 is a sapphire substrate, there is an advantage in that a film that is stable at a high temperature and that is a thin nitride film in a C (0001) face can be easily grown. Furthermore, if a patterned sapphire substrate (PSS) of such sapphire substrates is used as the substrate 110, there are advantages in that light efficiency and crystal quality are improved.

The first electrode 130 may be formed of a single layer or a plurality of stacked layers. The first electrode 130 is formed to come in contact with the second semiconductor layer 126 of the light-emitting structure 120 in the first and the second regions.

The first electrode 130 is not limited to specific conductive materials if the conductive materials capable of electrical connection and may be made of gold (Au), silver (Ag), copper (Cu), chrome (Cr), titanium (Ti), tungsten (W), nickel (Ni), silicon (Si), aluminum (Al), or molybdenum (Mo), for example, or an alloy or metal oxide including one or more of the types of metal.

In the light-emitting device to which an embodiment of the present invention is applied, light generated by the light-emitting structure 120 is externally extracted by passing the light through the substrate 110 functioning as a window. Accordingly, in order to improve such light extraction, the first electrode 130 may be made of conductive materials for reflecting light, emitted from the active layer 124 to the second semiconductor layer 126, toward the first semiconductor layer 122. In this case, the first electrode 130 may be made of one or more of pieces of metal selected from silver (Ag), nickel (Ni), aluminum (Al), rhodium (Rh), palladium (Pd), iridium (Ir), ruthenium (Ru), magnesium (Mg), zinc (Zn), platinum (Pt), and gold (Au), for example, or an alloy including two or more of the pieces of metal. In this case, light reflected by the first electrode 130 is directed toward a light-emitting surface of the first semiconductor layer 122, thereby being capable of improving light-emitting efficiency of the light-emitting device. The polarity of the first electrode 130 is determined by the characteristics of the second semiconductor layer 126 and may be an n type or p type.

The second electrode 140 may be formed to come in contact with the first semiconductor layer 122 along at least one edge of the substrate 110 in the first and the second regions. In FIG. 1, the second electrode 140 has been illustrated as being formed along the entire edge of the substrate 110.

Specifically, the second electrode 140 may include a line part 140a of a stripe shape formed along the edge of the substrate 110 on an exposed part of the first semiconductor layer 122 attributable to the etching of at least the second semiconductor layer 126 and the active layer 124.

For a smooth contact with the first bump 170, the second electrode 140 may include one or more line protrusions 140b that are protruded from the line part 140a formed along the edge of the substrate 110 to the inside of the substrate 110 in the first region. In this case, the line protrusion 140b may be formed in a corner or may be formed in a non-corner other than the corner. The line protrusion 140b may have various shapes, such as a circle, oval, or polygon. In FIG. 1, a circular line protrusion 140b has been illustrated as being formed on corners on both sides or at the center of the line part 140a on both sides in the first region.

In particular, in an embodiment of the present invention, the second electrode 140 may be formed of the same construct as part of or the entire first electrode 130. In this case, the construct means that the structure and component of a layer are the same. That is, part of or the entire second electrode 140 may be formed to include part of or the entire construction of the first electrode 130. Parts that belong to the first electrode 130 and the second electrode 140 and that have the same structure and component may be formed by a simultaneous process. If the second electrode 140 is formed to include the entire construction of the first electrode 130, the first electrode 130 and the second electrode 140 are formed of the same construct. The polarity of the second electrode 140 is determined by the characteristics of the first semiconductor layer 122 and may be an n type or p type.

As in an embodiment of the present invention, if the second electrode 140 electrically connected to the first bump 170 on the exposed part of the first semiconductor layer 122 is formed along the edge of the substrate 110, current spreading efficiency can be improved because an electric current flowing through the first semiconductor layer 122 can be uniformly spread over the entire light-emitting area.

Accordingly, light-emitting efficiency can be improved because a relatively uniform current flow is achieved over the entire light-emitting area.

In particular, the first electrode 130 and the second electrode 140 in accordance with an embodiment of the present invention may be formed by a simultaneous process.

That is, the first electrode 130 and the second electrode 140 may be formed in such a manner that a metal film or metal alloy film is deposited by a common physical vapor deposition (PVD) method, for example, a sputtering, electron beam (e-beam), or thermal evaporation method and then patterned by a common patterning method, for example, a photolithography process. Evaporation and etching may be properly combined depending on an element that belongs to the elements of the first electrode 130 and that is to be included in the second electrode 140 so that the second electrode 140 has the same construct as part of or the entire first electrode 130.

If the second electrode 140 is formed of the same construct as the first electrode 130, there is an advantage in that a process cost can be relatively reduced.

The light-emitting device to which an embodiment of the present invention is applied may further include the covering layer 150 configured to cover an exposed surface of the first electrode 130. The covering layer 150 may have one or more layers using a conductive ceramic film, such as SrTiO₃, Al-doped ZnO, indium in oxide (ITO), or indium zinc oxide (IZO) into which one or more impurities selected from gold (Au), nickel (Ni), tungsten (W), molybdenum (Mo), copper (Cu), aluminum (Al), titanium (Ti), tantalum (Ta), silver (Ag), platinum (Pt), chrome (Cr), and niobium (Nb), have been doped, a nickel (Ni) film, or a cobalt (Co) film, but the present invention is not specially limited thereto. Known materials may be used as the covering layer 150. The covering layer 150 may be formed by depositing a film using a common sputtering, e-beam, or thermal evaporation method and then patterning the film using a common photolithography process.

The insulating layer 160 may include a plurality of contact holes C1 and one or more second contact holes C2 formed in the first region and a plurality of third contact holes C3 formed in the second region, and may be formed to cover the light-emitting structure 120, the first electrode 130, and the second electrode 140.

The insulating layer 160 may be made of any common insulating materials and may be formed of a silicon oxide (SiO₂) film, a silicon nitride oxide (SiON) film, an aluminum nitride (AlN) film, an aluminum oxide (Al₂O₃) film, or a mixed film thereof, for example.

The first contact hole C1 may expose an exposed part of the first semiconductor layer 122 formed by etching in the first region, that is, at least part of the bottom of the trench T. One or more second contact holes C2 may be formed. The second contact hole C2 may expose at least part of the second electrode 140 formed in the first region. The third contact hole C3 may expose at least part of the first electrode 130 in the second region. If the covering layer 150 is additionally formed, the third contact hole C3 may be formed to expose at least part of the covering layer 150 as illustrated in FIG. 3. The first to third contact holes C1, C2, and C3 may be formed in such a manner that an insulating layer is formed by depositing common insulating materials on the light-emitting structure 120, the first electrode 130, and the second electrode 140 using a plasma enhanced chemical vapor deposition (PECVD) method, a sputtering method, an MOCVD method, an atomic layer deposition (ALD) method, or an e-beam evaporation method and then patterned using a common photolithography process so that desired regions of the first and the second regions can be exposed.

In an embodiment of the present invention, all the electrical connections of the first electrode 130 and the second electrode 140 may be implemented by flip chip bonding without wire bonding.

To this end, the first bump 170 may be formed on the insulating layer 160 of the first region of the substrate 110. The first bump 170 may be formed so that it is bonded to the first semiconductor layer 122 exposed through the first contact hole C1 and it is bonded to the second electrode 140 through the second contact hole C2.

Furthermore, the second bump 180 may be formed on the insulating layer 160 of the second region of the substrate 110. The second bump 180 may be formed so that it is bonded to the first electrode 130 through the third contact hole C3.

The first and the second bump 170, 180 may be made of metal materials, for example, a single piece of metal, such as lead (Pb), gold (Au), titanium (Ti), copper (Cu), nickel (Ni), in (Sn), chrome (Cr), tungsten (W), or platinum (Pt), or an alloy, such as Ti—W, W—Pt, Ni—Sn, Au—Sn, or Au—Ag and may be formed by depositing such materials using common sputtering and patterning the materials using a common photolithography process.

Although not illustrated, a submount substrate in which first and second conductive pads are provided in accordance with the first and the second bumps 170, 180 may be bonded to the first and the second bumps 170, 180.

The submount substrate is a substrate in which a light-emitting structure including the light-emitting structure 120 is mounted in a flip chip form and is spaced apart from the second electrode 140. The first and the second conductive pads may be provided in regions that belong to the submount substrate and on which the light-emitting structure is to be mounted.

The first and the second electrodes 130, 140 may be subject to flip chip bonding to the first and the second conductive pads that face each other through the first and the second bumps 170, 180. That is, the light-emitting structure including the light-emitting structure 120 and the submount substrate may be electrically bonded together with the first and the second bumps 170, 180 interposed therebetween.

In general, the first and the second conductive pads may be provided in order to apply external power to the first and the second electrodes 130, 140. The first and the second conductive pads may be made of metal materials, for example, a single piece of metal, such as, lead (Pb), gold (Au), titanium (Ti), copper (Cu), nickel (Ni), tin (Sn), chrome (Cr), tungsten (W), or platinum (Pt), or an alloy, such as Ti—W, W—Pt, Ni—Sn, Au—Sn, or Au—Ag. The first and the second conductive pads may be formed in such a manner that a conductive layer (not illustrated) is formed by depositing conductive materials using a PVD method or MOCVD method and then patterned by a photolithography process.

Accordingly, external power can be applied to the first semiconductor layer 122 through the second electrode 140 by the first bump 170 bonded to the first conductive pad and can be applied to the second semiconductor layer 126 through the first electrode 130 by the second bump 180 bonded to the second conductive pad.

In such a structure, if a contact with the first semiconductor layer 122 is formed up to the outskirt part of the substrate 110 and the second electrode 140 is formed along the edge of the substrate 110, light-emitting efficiency can be improved because uniform current spreading is achieved over the entire light-emitting area.

The embodiments of the present invention have been chiefly described, but it is evident to those skilled in the art to which the present invention pertains that the present invention may be changed or modified in various ways. Such changes and modifications may be considered to fall within the present invention unless they depart from the scope of a technical spirit provided by the present invention. Accordingly, the scope of the present invention should be determined the claims.

1. A light-emitting device, comprising:
a light-emitting structure formed over a substrate and configured to comprise a first semiconductor layer, an active layer, and a second semiconductor layer and to have a plurality of trenches formed up to the second semiconductor layer and the active layer;
a first electrode formed to come in contact with the second semiconductor layer of the light-emitting structure; and
a second electrode formed to come in contact with the first semiconductor layer of the light-emitting structure along at least one edge of the substrate.

2. The light-emitting device according to claim 1, wherein the first electrode has a single layer or a plurality of stacked layers.

3. The light-emitting device according to claim 1, wherein part of or the entire second electrode is formed of a construct identical with a construct of part of or the entire first electrode.

4. The light-emitting device according to claim 1, wherein one or more line protrusions are formed toward the substrate in part of the second electrode.

5. The light-emitting device according to claim 1, wherein the substrate comprises:
a first region defining a region corresponding to a first bump, and
a second region defining a region corresponding to a second bump.

6. The light-emitting device according to claim 5, further comprising:
an insulating layer formed over the first electrode, the second electrode, and the light-emitting structure and configured to comprise a plurality of first contact holes exposing the first semiconductor layer and one or more second contact holes exposing the second electrode within the first region and a plurality of third contact holes exposing the first electrode within the second region;
the first bump formed to be bonded to the first semiconductor layer through the first contact hole and bonded to the second electrode through the second contact hole over the insulating layer of the first region;
the second bump formed to be bonded to the first electrode through the third contact hole over the insulating layer of the second region; and
a submount substrate formed to be bonded to the first and the second bumps and configured to comprise first and second conductive pads in accordance with the first and the second bumps, respectively.

7. The light-emitting device according to claim 6, wherein one or more line protrusions are formed toward the substrate in part of the second electrode, the second contact hole is formed over the line protrusions.

8. The light-emitting device according to claim 6, further comprising a covering layer formed to cover an exposed surface of the first electrode between the first electrode and the insulating layer.

9. The light-emitting device according to claim 1, wherein:
the first semiconductor layer has an n type, and
the second semiconductor layer has a p type.

10. The light-emitting device according to claim 9, wherein:
the first electrode comprises a p-side electrode, and
the second electrode comprises an n-side electrode.

11. A method of manufacturing a light-emitting device, comprising:
forming a light-emitting structure comprising a first semiconductor layer, an active layer, and a second semiconductor layer over a substrate;
forming a plurality of trenches by etching at least the second semiconductor layer and the active layer; and
forming part of or the entire second electrode using a construct identical with a construct of part of or the entire first electrode along at least one edge of the substrate over the first semiconductor layer while forming the first electrode over the second semiconductor layer.

12. The method according to claim 11, wherein the first electrode has a single layer or a plurality of stacked layers.

13. The method according to claim 11, further comprising forming one or more line protrusions toward the substrate in part of the second electrode.

14. The method according to claim 11, wherein the second electrode and the first electrode are formed by a simultaneous process.

15. The method according to claim 11, wherein the trench is formed by a mesa etching process.

16. The method according to claim 11, wherein the substrate comprises:
a first region defining a region corresponding to a first bump, and
a second region defining a region corresponding to a second bump.

17. The method according to claim 16, further comprising:
forming an insulating layer, comprising a plurality of contact holes exposing the first semiconductor layer and one or more second contact holes exposing the second electrode within the first region and a plurality of third contact holes exposing the first electrode within the second region, over the first electrode, the second electrode, and the light-emitting structure;
forming the first bump bonded to the first semiconductor layer through the first contact hole and bonded to the second electrode through the second contact hole over the insulating layer of the first region;
forming the second bump bonded to the first electrode through the third contact hole over the insulating layer of the second region; and
bonding a submount substrate, comprising first and second conductive pads respectively corresponding to the first and the second bumps, to the first and the second bumps.

18. The method according to claim 11, further comprising forming a covering layer which covers an exposed surface of the first electrode before forming the insulating layer.
